(19) United States
(12) Patent Application Publication
(10) Pub. No.: US 2013/0295768 A1
(43) Pub. Date: Nov. 7, 2013

(54) SUBSTRATE PROCESSING APPARATUS AND METHOD OF MANUFACTURING SEMICONDUCTOR DEVICE

(71) Applicant: Tadashi Horie, Toyama-shi (JP)

(72) Inventor: Tadashi Horie, Toyama-shi (JP)

(73) Assignee: Hitachi Kokusai Electric Inc., Tokyo (JP)

(21) Appl. No.: 13/996,882

(22) PCT Filed: Dec. 22, 2011
(86) PCT No.: PCT/JP2011/079908

§ 371 Date: Jun. 21, 2013

(30) Foreign Application Priority Data
Dec. 22, 2010 (JP) 2010-285774

(51) Int. Cl. H01L 21/67; H01L 21/02

(52) U.S. Cl. CPC H01L 21/67011; H01L 21/02697
USPC 438/685; 118/723 R

(57) ABSTRACT

A process chamber is provided into which a substrate is carried, wherein a chlorine atom-containing metal nitride film, in which a natural oxide film is formed on a top side thereof, is formed on the substrate; a substrate support unit configured to support and heat the substrate within the process chamber; a gas supply unit configured to supply either or both of nitrogen atom-containing gas and hydrogen atom-containing gas to an inside of the process chamber; a gas exhaust unit configured to exhaust the gas from the inside of the process chamber; a plasma generation unit configured to excite the nitrogen atom-containing gas and the hydrogen atom-containing gas supplied to the inside of the process chamber; and a control unit configured to control the substrate support unit, the gas supply unit, and the plasma generation unit.

### TECHNICAL FIELD

The present invention relates to a substrate processing apparatus that processes a substrate using plasma, and a method of manufacturing a semiconductor device.

### BACKGROUND ART

In a semiconductor logic device, a DRAM device and the like, in order to suppress an increase in an electric resistance accompanying down-scaling, a metal nitride film for example containing titanium nitrides (hereafter simply referred to as titanium nitride (TiN) film) is employed as a material of electrodes, wirings and the like. The metal nitride film can be formed for example by a chemical vapor deposition (CVD) method, or an atomic layer deposition (ALD) method. In order to form the titanium nitride film by such methods, a titanium tetrachloride (TiCl₄) gas containing chlorines is used as a precursor gas. A method of forming the titanium nitride film is described for example in Patent Document 1.

### CITATION LIST

### Patent Document

Patent Document 1: WO2007/020874

### SUMMARY

### Problems to be Solved by the Invention

However, it has been found by a research of the inventors that impurities such as chlorine atoms, carbon atoms and the like remain in a film when a titanium nitride film is formed by the aforementioned methods. Especially, in a case of using a titanium tetrachloride gas as a precursor gas, chlorine atom residues in the titanium nitride film become prominent. Residual substances such as the chlorine atoms, the carbon atoms and the like increase an electric resistance of the titanium nitride film, and it becomes difficult to form a film that satisfies properties required in down-scaling of integrated circuits and in improving device properties in the recent years.

The chlorine atoms can be removed by forming the titanium nitride film under a high temperature, or by performing a high temperature treatment on the titanium nitride film after having formed the same. However, if the high temperature treatment is performed on titanium nitride films formed for example for an upper electrode and a lower electrode of a DRAM capacitor, properties of a capacitance insulating film and the like sandwiched by the titanium nitride films are deteriorated, whereby in some cases a leak current is increased. Further, in some cases, a circuit property may be deteriorated due to an occurrence of diffusion in a source region and a drain region formed on a substrate in advance, whereby a performance of a semiconductor device may be reduced. Nonetheless, if a process of removing the chlorine atoms is performed in a temperature range by which the aforementioned property deterioration and diffusion would not occur, it then becomes difficult to sufficiently remove the residual chlorines.

Further, a surface of the titanium nitride film is naturally oxidized, and is of a layer containing a large content of oxygen atoms. The oxygen atoms remaining in the titanium nitride film increase the electric resistance of the titanium nitride film. Further, the oxygen atoms change an interfacial property of the titanium nitride film and the capacitance insulating film and the like formed on top thereof, and deteriorate device properties.

Further, in a case of forming the upper electrode and the lower electrode of the DRAM by the titanium nitride films, although a metal oxide film and the like that is the capacitance insulating film is formed after having formed the titanium nitride film as the lower electrode, in some cases the titanium nitride film as the lower electrode is oxidized upon forming the metal oxide film, and the device properties may thereby be deteriorated.

An object of the present invention is to provide a metal processing apparatus, and a method of manufacturing a semiconductor device that can achieve one or both of reducing a chlorine atom residual amount and an oxygen atom residual amount in a metal nitride film and improving an oxidation resistance property of the metal nitride film in a temperature range by which properties of other films adjacent to the metal nitride film are not deteriorated.

### Solutions to Problems

According to one embodiment, there is provided a substrate processing apparatus including: a process chamber into which a substrate is carried, wherein a chlorine atom-containing metal nitride film, in which a natural oxide film is formed on a top side thereof, is formed on the substrate; a substrate support unit configured to support and heat the substrate within the process chamber; a gas supply unit configured to supply either or both of nitrogen atom-containing gas and hydrogen atom-containing gas to an inside of the process chamber; a gas exhaust unit configured to exhaust the gas from the inside of the process chamber; a plasma generation unit configured to excite the gas supplied to the inside of the process chamber; and a control unit configured to control the substrate support unit, the gas supply unit, and the plasma generation unit.

According to another embodiment, there is provided a method of manufacturing a semiconductor device, the method including: carrying a substrate into a process chamber and supporting the substrate by a substrate support unit, wherein a chlorine atom-containing metal nitride film, in which a natural oxide film is formed on a top side thereof, is formed on the substrate; heating the substrate by the substrate support unit; supplying, by a gas supply unit, either or both of nitrogen atom-containing gas and hydrogen atom-containing gas to an inside of the process chamber; and exciting, by a plasma generation unit, the gas supplied to the inside of the process chamber.

### Effects

According to the substrate processing apparatus and the method of manufacturing a semiconductor device according to the invention, residual amounts of chlorine atoms and oxygen atoms in the metal nitride film can be reduced in a temperature range in which properties of other films adjacent to the metal nitride film are not deteriorated, and an oxidation resistance can be improved while improving properties of the metal nitride film.

### BRIEF DESCRIPTION OF DRAWINGS

FIG. 1 is a schematic cross-sectional view of a substrate processing apparatus that performs a method of manufacturing a semiconductor device according to an embodiment.

FIG. 2 is a graph showing an example of a concentration of chlorine atoms in a titanium nitride film.

FIG. 3 is a graph showing a temperature dependence of a sheet resistance of the titanium nitride film.

FIG. 4 is a graph showing an example of a change in the sheet resistance of the titanium nitride film.

FIG. 5 is a table showing a composition ratio of the titanium nitride film.

FIG. 6 is a graph showing an example of the change in the sheet resistance of the titanium nitride film upon being exposed to an oxygen atmosphere.

FIG. 7 is a graph showing an example of a change in a sheet resistance ratio when processing is performed by changing a ratio between a nitrogen gas and a hydrogen gas.

FIG. 8 is a graph showing an example of the change in the sheet resistance ratio when processing is performed by changing a ratio between the nitrogen gas and an ammonia gas.

FIG. 9 is a graph showing an example of a change in TiOₓ and TiNₓ concentrations within a film when processing is performed by changing a voltage Vpp of a second electrode.

FIG. 10 is a graph showing an example of a change in a chlorine concentration within the film when processing is performed by changing the voltage Vpp of the second electrode.

### DESCRIPTION OF EMBODIMENT

As described above, when high temperature processing for example at 750° C. or more is performed on a titanium nitride film, properties of other films adjacent to the titanium nitride film are deteriorated, and in some cases a leaking current of a capacitor of a DRAM for example may be increased. Further, there may be cases where a circuit property is deteriorated by diffusions occurring in a source region and a drain region formed in advance on a substrate, and a performance of a semiconductor device is decreased. On the other hand, if a process of removing chlorine atoms is performed in a temperature range in which the properties of the films adjacent to the titanium nitride film are not deteriorated, it becomes difficult to sufficiently remove residual chlorine.

In regards to this, the inventors have conducted intensive studies on a method of improving an oxidation resistance of a titanium nitride film while reducing the residual amounts of chlorine and oxygen within the titanium nitride film in the temperature range in which the properties of the other films adjacent to the titanium nitride film are not deteriorated. As a result, the inventors have found that the above problem can be solved by activating a gas, in which a hydrogen atom-containing gas is mixed with a nitrogen atom-containing gas, by using plasma, and supplying the activated gas to the titanium nitride film formed on the substrate. The invention has been made based on the above discovery achieved by the inventors. An embodiment will be described below.

### (1) Configuration of Substrate Processing Apparatus

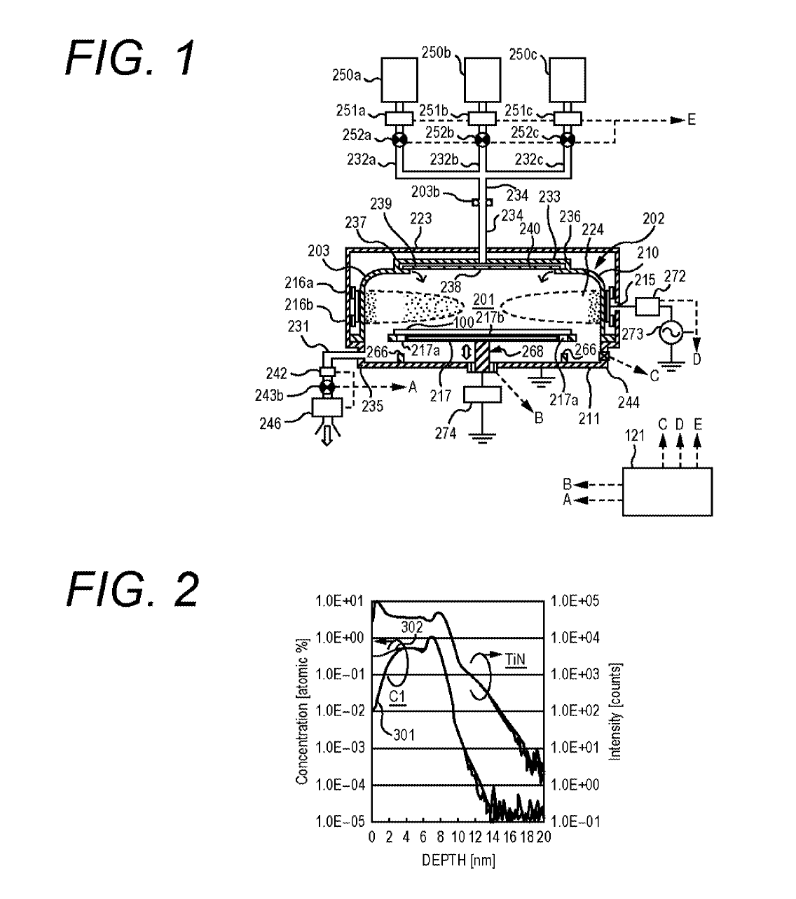

First, an exemplary configuration of a substrate processing apparatus that performs a method of manufacturing a semiconductor device of the embodiment will be described with reference to FIG. 1. FIG. 1 is a cross-sectional configuration diagram of an MMT apparatus as the substrate processing apparatus. The MMT apparatus uses a modified magnetron typed plasma source that can generate highly concentrated plasma by an electric field and a magnetic field. The MMT apparatus is, for example, an apparatus that performs plasma processing on a silicon substrate 100 such as a silicon wafer.

The MMT apparatus includes a processing furnace 202 that performs plasma processing on the silicon substrate 100. The processing furnace 202 includes a processing container 203 that configures a process chamber 201, a susceptor 217, a gate valve 244, a shower head 236, a gas exhaust opening 235, a cylindrical electrode 215, an upper magnet 216a, a lower magnet 216b, and a controller 121.

The processing container 203 configuring the process chamber 201 includes a dome-shaped upper container 210 that is a first container, and a bowl-shaped lower portion container 211 that is a second container. Further, the process chamber 201 is formed by the lower container 211 being covered with the upper container 210. The upper container 210 is formed of a nonmetallic material such as aluminum oxide (Al₂O₃) or quartz (SiO₂), and the lower container 211 is formed of, for example, aluminum (Al).

A susceptor 217 supporting the silicon substrate 100 is disposed at the center on a bottom side in the process chamber 201. The susceptor 217 is formed of a nonmetallic material such as aluminum nitride (AlN), ceramics, or quartz so as to reduce metallic contamination of a film formed on the silicon substrate 100.

A heater 217b as a heating mechanism is integrally embedded inside the susceptor 217, and is configured to heat the silicon substrate 100. When power is supplied to the heater 217b, it is capable of heating a surface of the silicon substrate 100 to, for example, about 200 to 750° C.

A substrate support unit of the embodiment mainly includes the susceptor 217, the heater 217b, and a second electrode 217c.

The susceptor 217 is electrically insulated from the lower container 211. A second electrode (not shown) as an electrode for changing an impedance is installed inside the susceptor 217. The second electrode is arranged via an impedance changing mechanism 274. The impedance changing mechanism 274 includes coils and variable capacitors, and is configured to control a potential of the silicon substrate 100 via the second electrode 217c and the susceptor 217 by controlling a pattern number of coils and capacity values of the variable capacitors.

A susceptor lifting mechanism 268 for lifting and lowering the susceptor 217 is provided in the susceptor 217. The susceptor 217 has through holes 217a provided therein. At least three wafer push-up pins 266 for pushing the silicon substrate 100 upward are provided on a bottom surface of the aforementioned lower container 211. Further, the through holes 217a and the wafer push-up pins 266 are arranged relative to one another so that the wafer push-up pins 266 penetrate the through holes 217a without coming into contact with the susceptor 217 when the susceptor 217 is lowered by the susceptor lifting mechanism 268.

A gate valve 244 as a gate valve is provided on a side wall of the lower container 211. When the gate valve 244 is open, the silicon substrate 100 can be introduced into the process chamber 201 by using a transfer mechanism (not shown), or the silicon substrate 100 can be taken out of the process chamber 201. By closing the gate valve 244, the process chamber 201 can be airtightly closed.

The shower head 236 for supplying a gas into the process chamber 201 is provided at an upper portion of the process chamber 201. The shower head 236 includes a cover body 233 on a cap, a gas inlet 234, a buffer chamber 237, an opening 238, a blocking plate 240, and a gas outlet 239.

A downstream end of a gas supplying pipe 232 for supplying a gas into the buffer chamber 237 is connected to the gas inlet 234 via an O-ring 203b as a sealing member. The buffer chamber 237 functions as a dispersing space for dispersing the gas introduced through the gas inlet 234.

A downstream end of a nitrogen gas supplying pipe 232a for supplying an N₂ gas as a nitrogen atom-containing gas, a downstream end of a hydrogen gas supplying pipe 232b for supplying an H₂ gas as a hydrogen atom-containing gas, and a downstream end of a noble gas supplying pipe 232c for supplying a noble gas such as helium (He) and argon (Ar) as a dilution gas are connected to, and joined at, an upstream side of the gas supplying pipe 234.

A nitrogen gas cylinder 250a, a mass flow controller 251a as a flow rate controlling apparatus, and a valve 252a as an on-off valve are connected to the nitrogen gas supplying pipe 232a in order from an upstream side. A hydrogen gas cylinder 250b, a mass flow controller 251b as a flow rate controlling apparatus, and a valve 252b as an on-off valve are connected to the hydrogen gas supplying pipe 232b in order from an upstream side. A noble gas cylinder 250c, a mass flow controller 251c as a flow rate controlling apparatus, and a valve 252c as an on-off valve are connected to the noble gas supplying pipe 232c in order from an upstream side.

A gas supply unit of the embodiment mainly includes the gas supplying pipe 234, the nitrogen gas supplying pipe 232a, the hydrogen gas supplying pipe 232b, the noble gas supplying pipe 232c, the nitrogen gas cylinder 250a, the hydrogen gas cylinder 250b, the noble gas cylinder 250c, the mass flow controllers 251a to 252c, and the valves 252a to 252c. The gas supplying pipe 234, the nitrogen gas supplying pipe 232a, the hydrogen gas supplying pipe 232b, and the noble gas supplying pipe 232c are formed of a nonmetallic material such as quartz or aluminum oxide, and a metallic material such as SUS. The gas supplying pipes are configured to arbitrarily supply the N₂ gas, the H₂ gas, and the noble gas into the process chamber 201 via the buffer chamber 237 by opening and closing of these valves 252a to 252c and flow rate control by the mass flow controllers 251a to 252c.

Although a case of providing the gas cylinder for each of the N₂ gas, the H₂ gas, and the noble gas has been described here, the invention is not limited to such an embodiment, and an ammonia (NH₃) gas cylinder may be provided instead of the nitrogen gas cylinder 250a and the hydrogen gas cylinder 250b. Further, to increase a ratio of nitrogen in a reactant gas supplied into the process chamber 201, an N₂ gas cylinder may further be provided to add the N₂ gas to the NH₃ gas.

A gas exhaust opening 235 for exhausting the reactant gas and the like from the process chamber 201 is provided on a lower portion of the side wall of the lower container 211. An upstream end of a gas exhaust pipe 231 for exhausting a gas is connected to the gas exhaust opening 235. An APC 242 that is a pressure regulator, a valve 243b that is an on-off valve, and a vacuum pump 246 that is an exhaust apparatus are provided on the gas exhaust pipe 231 in order from an upstream side. A gas exhaust unit of the embodiment mainly includes the gas exhaust opening 235, the gas exhaust pipe 231, the APC 242, the valve 243b, and the vacuum pump 246. The gas exhaust unit is configured to exhaust the interior of the process chamber 201 by activating the vacuum pump 246 and opening the valve 243b. Further, the gas exhaust unit is configured to adjust a pressure value inside the process chamber 201 by adjusting a divergence of the APC 242.

A cylindrical electrode 215 as a first electrode is provided on an outer periphery of the processing container 203 (upper container 210) so as to surround a plasma generating region 224 within the process chamber 201. The cylindrical electrode 215 is formed cylindrically, for example, in the form of a round cylinder. The cylindrical electrode 215 is connected, via an impedance matching box 272 that performs matching of impedances, to a high frequency power source 273 that generates high frequency power. The cylindrical electrode 215 functions as a discharge mechanism that excites the gas to be supplied into the process chamber 201 to thereby generate plasma.

An upper magnet 216a and a lower magnet 216b are respectively attached to upper and lower end portions on an outer surface of the cylindrical electrode 215. The upper magnet 216a and the lower magnet 216b are each configured as a permanent magnet formed cylindrically, for example, in the form of a ring.

The upper magnet 216a and the lower magnet 216b each include magnetic poles on both ends along a radial direction of the process chamber 201 (that is, on an inner circumferential end and an outer circumferential end of each magnet). Orientations of the magnetic poles of the upper magnet 216a and the lower magnet 216b are disposed so as to be opposite to one another. That is, the magnetic poles on inner circumferential portions of the upper magnet 216a and the lower magnet 216b are of different poles. Due to this, a line of magnetic force in a cylindrical axis direction is formed along an inner surface of the cylindrical electrode 215.

A plasma generation unit of the embodiment mainly includes the cylindrical electrode 215, the impedance matching box 272, the high frequency power source 273, the upper magnet 216a, and the lower magnet 216b. By forming an electric field by supplying the high frequency power to the cylindrical electrode 215, and forming a magnetic field by using the upper magnet 216a and the lower magnet 216b after having introduced a mixed gas of the N₂ gas and the H₂ gas into the process chamber 201, magnetron discharge plasma is generated in the process chamber 201. At this occasion, an ionization rate of the plasma is increased by the aforementioned electromagnetic field causing discharged electrons to move orbitally, and the plasma with long life and high density can be generated.

Note that a metallic blocking plate 223 for effectively blocking the electromagnetic field is provided around the cylindrical electrode 215, the upper magnet 216a, and the lower magnet 216b so that the electromagnetic field formed thereby does not adversely affect an external environment or an apparatus such as another processing furnace.

Further, the controller 121 as a control unit is configured to control the APC 242, the valve 243b, and the vacuum pump 246 through a signal line A, to control the susceptor lifting mechanism 268 through a signal line B, to control the gate valve 244 through a signal line C, to control the impedance matching box 272 and the high frequency power source 273 through a signal line D, to control the mass flow controllers 251a to 252c and the valves 252a to 252c through a signal line E, and further to control a heater embedded in the susceptor and the impedance changing mechanism 274 through a signal line not shown.

### (2) Substrate Processing Step

Next, a substrate processing step that is performed as one of the steps in a semiconductor manufacturing step of the embodiment will be described. This step is performed by the aforementioned MMT apparatus as the substrate processing apparatus. Note that in the following description, operations of respective units configuring the MMT apparatus are controlled by the controller 121. Here, an example in which a metal nitride film (titanium nitride film) formed as a lower electrode of a capacitor is subjected to nitriding by using plasma will be described.

### (Introduction of Substrate)

First, the susceptor 217 is lowered to a transporting position of the silicon substrate 100, and the wafer push-up pins 266 are inserted into the through holes 217a of the susceptor 217. As a result, the push-up pins 266 protrude from a surface of the susceptor 217 by a predetermined height.

Then, the gate valve 244 is opened, and the silicon substrate 100 is introduced into the process chamber 201 by using a transporting mechanism that is not shown. As a result, the silicon substrate 100 is horizontally supported on the wafer push-up pins 266 protruding from the surface of the susceptor 217. On the silicon substrate 100, the titanium nitride film as the lower electrode of the capacitor is formed in advance by a CVD method or an ALD method. The titanium nitride film is formed by another CVD apparatus or ALD apparatus (not shown) using a titanium tetrachloride (TiCl₄) gas containing chlorines as a precursor gas. Note that since the titanium tetrachloride gas is used as the precursor gas, chlorine atoms are remaining in the titanium nitride film. Further, a natural oxide film is formed on a surface of the titanium nitride film. The natural oxide film is formed when the silicon substrate 100 is introduced into the process chamber 201 from the aforementioned CVD apparatus or ALD apparatus.

Upon introducing the silicon substrate 100 into the process chamber 201, the transporting mechanism is evacuated to the outside of the process chamber 201, and the process chamber 201 is sealed by closing the gate valve 244. Then, by using the susceptor lifting mechanism 268, the susceptor 217 is lifted. As a result, the silicon substrate 100 is disposed on an upper surface of the susceptor 217. Thereafter, the susceptor 217 is lifted to a predetermined position, and the silicon substrate 100 is lifted to a predetermined processing position.

Note that, to introduce the silicon substrate 100 into the process chamber 201, it is preferable to supply the N₂ gas and the noble gas as inactive gases from a gas supplying line to fill the process chamber 201 with the inactive gases, and reduce an oxygen concentration while the process chamber 201 is exhausted by a gas exhaust line. That is, it is preferable to supply the inactive gas into the process chamber 201 via the buffer chamber 237 by opening the valve 243a or the valve 243c while the process chamber 201 is exhausted by activating the vacuum pump 246 and opening the valve 243b.

### (Temperature Rise in Substrate)

Next, power is supplied to a heater 217h embedded inside the susceptor 217, and the surface of the silicon substrate 100 is heated. A surface temperature of the silicon substrate 100 is preferably a temperature that is 200° C. or more and less than 750° C., more preferably 200° C. or more and 700° C. or less.

Note that, in a heating process of the silicon substrate 100, when the surface temperature is heated to 750° C. or more, diffusion occurs in a source region and a drain region formed in the silicon substrate 100, which may deteriorate a circuit property and decrease a performance of a semiconductor device. By limiting the temperature of the silicon substrate 100 as above, the diffusion of impurities in the source region and the drain region formed in the silicon substrate 100, the deterioration of the circuit property, and the decrease in the performance of the semiconductor device can be suppressed. In the following description, the surface temperature of the silicon substrate 100 is set at, for example, 450° C.

### (Introduction of Reactant Gas)

Here, an example of using a mixed gas of the N₂ gas and the H₂ gas as the reactant gas will be described.

First, the valves 252a and 252b are opened to introduce (supply) the reactant gas that is the mixed gas of the N₂ gas and the H₂ gas into the process chamber 201 via the buffer chamber 237. At this occasion, divergences of the mass flow controllers 251a and 251b are respectively controlled so as to cause a flow rate of the N₂ gas included in the reactant gas and a flow rate of the H₂ gas included in the reactant gas become predetermined flow rates. The flow rate of the H₂ gas to be supplied into the process chamber 201 is in a range of 0 sccm or more and 600 sccm or less. Further, the flow rate of the N₂ gas to be supplied into the process chamber 201 is in a range of 0 sccm or more and 600 sccm or less. Note that, in this occasion, the valve 252c may be opened to supply the noble gas as the dilution gas into the process chamber 201, and a concentration of the mixed gas of the N₂ gas and the H₂ gas to be supplied into the process chamber 201 may be adjusted. A ratio of nitrogen atoms to hydrogen atoms contained in the gases supplied into the process chamber 201 is in a range of 0 or more and 100 or less.

Further, after having started the introduction of the reactant gas into the process chamber 201, the vacuum pump 246 and the APC 242 are used to adjust a pressure within the process chamber 201 to be in a range of 0.1 to 300 Pa, more preferably 0.1 to 100 Pa, for example 30 Pa.

### (Excitation of Reactant Gas)

After having started the introduction of the reactant gas, magnetron discharge is generated in the process chamber 201 by applying high frequency power to the cylindrical electrode 215 from the high frequency power source 273 via the impedance matching box 272, and applying a magnetic force by the upper magnet 216a and the lower magnet 216b into the process chamber 201. As a result, highly concentrated plasma is generated in the plasma generating region 224 above the silicon substrate 100. Note that the power to be applied to the cylindrical electrode 215 is in a range of, for example, 100 to 3000 W, for example, 800 W. At this occasion, a voltage Vpp can be applied to the silicon substrate 100 via the second electrode 217c provided on the susceptor 217. The voltage Vpp is controlled by the impedance changing mechanism 274 connected to the second electrode 217c. An impedance value (voltage Vpp) is controlled beforehand to a desired value after having introduced the substrate.

By forming a plasma state as aforementioned, the N₂ gas and the H₂ gas supplied into the process chamber 201 are excited and activated. Further, nitrogen radicals (N*) and hydrogen radicals (H*) generated thereby react with the surface of the silicon substrate 100. In this reaction, reduction by the hydrogen, and collision and replenishment of nitrogen atoms to the surface of the titanium nitride film are performed. As a result, a hydrogen chloride gas is generated by the reaction between chlorine components and the hydrogen, and an aqueous (H₂O) gas is generated by the reaction between oxygen components and the hydrogen. Both of the generated gases are discharged to the outside of the titanium nitride film. Further, the nitrogen atoms are introduced into the titanium nitride film, and the titanium nitride film with a stronger bonding degree is formed. Chemical reaction formulas in the reaction are shown below.

TiCl+N*+H*→*TiN+HCl↑ (Formula 1)

TiO+N*+2H*→*TiN+H₂O↑ (Formula 2)

### (Exhaust of Residual Gas)

When the nitriding of the titanium nitride film has ended, the power supply to the cylindrical electrode 215 is stopped, and the valves 252a and 252b are closed to stop the gas supply into the process chamber 201. Then, the residual gas within the process chamber 201 is exhausted using the gas exhaust pipe 231. Further, the susceptor 217 is lowered to the transporting position of the silicon substrate 100, and causes the silicon substrate 100 to be supported on the wafer push-up pins 266 protruding from the surface of the susceptor 217. Then, the gate valve 244 is opened, the silicon substrate 100 is taken out of the process chamber 201 by using the transporting mechanism that is not shown, and the substrate processing step of the embodiment ends.

### (3) Advantageous Effects of the Embodiment

According to the embodiment, one or more of the advantageous effects described below can be achieved.

(a) According to the embodiment, the residual amount of the chlorine atoms in the titanium nitride film can be reduced, a quality of the titanium nitride film can be improved, and an electric resistance of the titanium nitride film can be reduced.

FIG. 2 is a graph showing the concentration of the chlorine atoms in the titanium nitride film before and after the aforementioned substrate processing step. A vertical axis of FIG. 2 shows a density (atomic %) of the chlorine atoms in the titanium nitride film, and a horizontal axis shows a depth (nm) from the surface of the titanium nitride film. According to FIG. 2, it can be understood that the density of the chlorine atoms is decreased from the surface of the titanium nitride film to the depth of about 4 nm. That is, it can be understood that the residual amount of the chlorine atoms in the titanium nitride film can be reduced by performing the aforementioned substrate processing step.

(b) According to the embodiment, the residual amount of the oxygen atoms in the titanium nitride film can be reduced, and the electric resistance of the titanium nitride film can be reduced. Further, introduction of the nitrogen atoms into the titanium nitride film is enhanced, whereby the bonding degree of the titanium nitride film can be increased, and the electric resistance of the titanium nitride film can be reduced.

FIG. 5 is a result of evaluating a composition ratio of the titanium nitride film before and after the aforementioned substrate processing step by an X-ray photoelectron spectroscopy method. In this measurement, a composition at the depth of about 4 nm from the surface of the titanium nitride film is analyzed. According to FIG. 5, it can be understood that the composition ratio of the oxygen atoms is reduced, and the composition ratios of the nitrogen atoms and titanium atoms are each increased. That is, it can be understood that, by performing the aforementioned substrate processing step, the titanium nitride film with stronger bonding degree is formed by the oxygen atoms in the titanium nitride film being removed and nitriding of the titanium nitride film being enhanced due to the introduction of the nitrogen atoms into the titanium nitride film. Further, it can also be understood that the residual amount of carbon atoms is reduced.

(c) According to the embodiment, the aforementioned substrate processing step is performed at a temperature of 200° C. or more and less than 750° C. (hereinafter referred to as a processing temperature region), or preferably at a temperature of 200° C. or more and 700° C. or less. As a result, the electric resistance of the titanium nitride film can be reduced, and a property thereof can be improved.

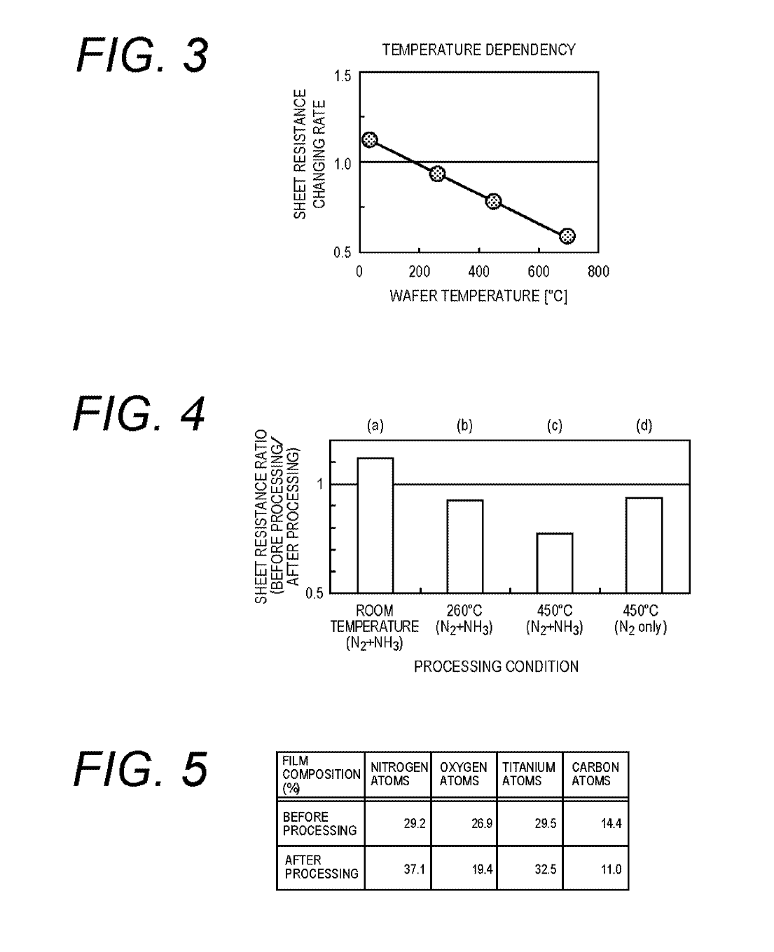

FIG. 3 is a graph showing a temperature dependence of a sheet resistance of the titanium nitride film when the substrate process is performed at a temperature including the aforementioned processing temperature region. In FIG. 3, a ratio of the sheet resistance (sheet resistance changing ratio) of the titanium nitride film after having performed the substrate processing step with the sheet resistance (Ω/square) of the titanium nitride film before performing the aforementioned substrate process as 1 (reference). The processing temperature (surface temperature of the silicon substrate 100) is set at a room temperature to 700° C., and the plasma processing is performed by using the mixed gas of the N₂ gas and the H₂ gas. According to FIG. 3, it can be understood that the sheet resistance changing rate becomes 1 or less when the processing temperature is set to be 200° C. or more. It can be therefore understood that a film quality is improved better as the processing temperature is set higher as well as 200° C. or more. However, when the processing is performed at a temperature of 750° C. or more, there is a problem in that the performance of the semiconductor device formed on the silicon substrate 100 is decreased. This problem is caused by the diffusion occurring in the source region and the drain region, and the circuit property being deteriorated. Thus, in the present process, it is preferable to set the processing temperature to be 200° C. or more and less than 750° C.

FIG. 4 is a graph showing a change in the sheet resistance of the titanium nitride film when the aforementioned substrate processing step is performed. In FIG. 4, the ratio of the sheet resistance (sheet resistance ratio) of the titanium nitride film after having performed the substrate processing step with the sheet resistance (Ω/square) of the titanium nitride film before performing the aforementioned substrate processing step as 1 (reference). Note that in FIG. 4(a), the processing temperature (surface temperature of the silicon substrate 100) is set at the room temperature, and the plasma processing is performed by using a mixed gas of the N₂ gas and an NH₃ gas. In FIG. 4(b), the processing temperature is set at 260° C., and the plasma processing is performed by using the mixed gas of the N₂ gas and the NH₃ gas. In FIG. 4(c), the processing temperature is set at 450° C., and the plasma processing is performed by using the mixed gas of the N₂ gas and the NH₃ gas. In FIG. 4(d), the processing temperature is set at 450° C., and the plasma processing is performed by using only the N₂ gas.

According to FIG. 4, in all of the cases where the processing temperature is set to a temperature in the processing temperature region (cases of FIG. 4(b) to (d)), it can be understood that the sheet resistance can be reduced by performing the aforementioned substrate processing step. Contrary to this, in the case where the processing temperature is set to the room temperature (case of FIG. 4(a)), it can be understood that the sheet resistance is increased by performing the plasma processing.

Note that, as shown in FIG. 4(b), by using the mixed gas of the N₂ gas and the NH₃ gas as the reactant gas, it can be understood that similar or greater advantageous effects to/than (d) in FIG. 4 setting the processing temperature at 450° C. can be achieved in an atmosphere of only the N₂ gas, despite the processing temperature being low, namely, 260° C. This is assumed to result from a hydrogen component included in the NH₃ gas enhancing the removal of chlorine atoms remaining in the titanium nitride film.

Further, as shown in FIG. 4(c), it can be understood that, by using the mixed gas of the N₂ gas and the NH₃ gas as the reactant gas and increasing the processing temperature to 450° C., the sheet resistance ratio can more effectively be reduced. That is, it can be understood that, by increasing the processing temperature, the removal of the chlorine atoms from the silicon nitride film can be enhanced. However, such high temperature processing needs to be performed in the temperature range that does not deteriorate a property of films adjacent to the titanium nitride film (that is, at a temperature of 200° C. or more and less than 750° C. (processing temperature region), more preferably at a temperature of 200° C. or more and 700° C. or less).

(d) According to the embodiment, an oxidation resistance of the titanium nitride film can be improved. As a result, natural oxidization of the titanium nitride film can be suppressed, and the electric resistance of the titanium nitride film can be reduced. Further, to form a metal oxide film and the like as a capacitance insulating film by using an oxidizing agent such as O₂ or O₃ on the titanium nitride film as the lower electrode of the DRAM, the oxidization of the titanium nitride film by the oxidizing agent can be suppressed, and an interfacial quality can be improved.

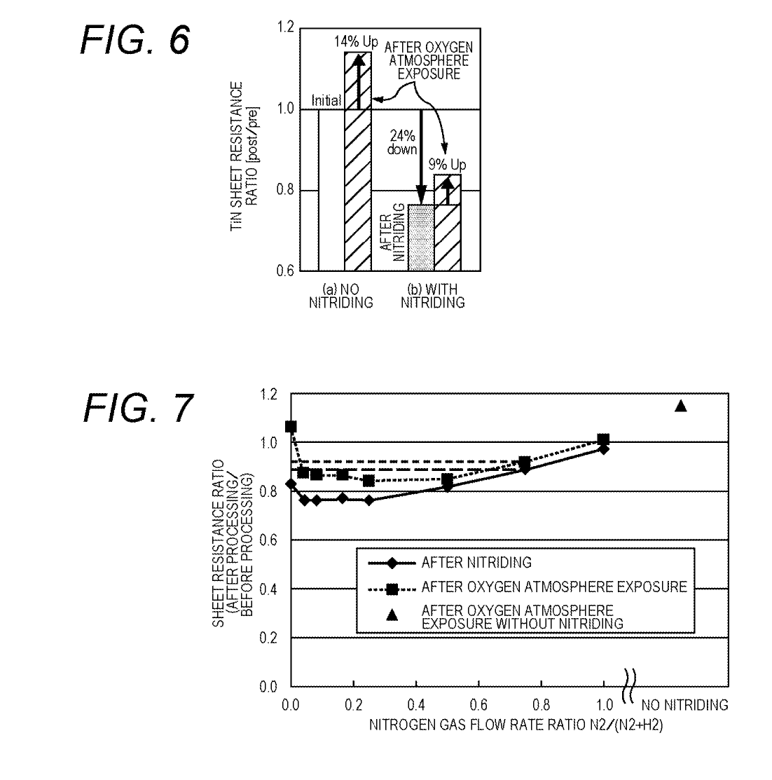

FIG. 6 is a graph showing a change in the sheet resistance of the titanium nitride film upon being exposed to an oxygen (O₂) atmosphere. Note that the exposure to the oxygen (O₂) atmosphere was performed for 120 seconds with an O₂ gas atmosphere, a gas pressure of 200 Pa, and a wafer temperature of 450° C. FIG. 6(a) shows the change in the sheet resistance ratio of the titanium nitride film to which the aforementioned substrate processing step has not been performed, FIG. 6(b) shows the change in the sheet resistance ratio of the titanium nitride film to which the aforementioned substrate processing step has been performed. Both of them set a value of the sheet resistance of the titanium nitride film to which the aforementioned substrate processing step has not been performed and that is before being exposed to the oxygen atmosphere as 1 (reference).

As shown in FIG. 6, it can be understood that the sheet resistance of the titanium nitride film is reduced by 24% by performing the aforementioned substrate processing step. Further, although the sheet resistance of the titanium nitride film increases by being exposed to the oxygen atmosphere, it can be understood that an increase in the sheet resistance is suppressed in the titanium nitride film to which the aforementioned substrate processing step has been performed compared to the titanium nitride film to which the substrate processing step has not been performed. That is, it can be understood that the increase in the value of the sheet resistance in the titanium nitride film to which the substrate processing step has not been performed is 14%, whereas in the titanium nitride film to which the substrate processing step has been performed, the increase in the value of the sheet resistance is suppressed to 9%. Accordingly, it can be understood that an oxidation resistance of the titanium nitride film can be improved by performing the aforementioned substrate processing step.

(e) Further, according to the embodiment, the highly concentrated plasma is generated in the vicinity of the silicon substrate 100, that is, in the plasma generating region 224 above the silicon substrate 100, and the nitrogen radicals (N*) and the hydrogen radicals (H*) are generated inside the process chamber 201. Therefore, the generated radicals can effectively be supplied to the titanium nitride film before being deactivated. Further, a processing speed of the aforementioned substrate processing (nitriding using the plasma) can be improved. Note that in a remote plasma method of generating plasma outside the process chamber 201 to generate radicals thereat, the generated radicals tend to be deactivated before being supplied to the silicon substrate 100, and it is difficult to effectively supply the radicals to the silicon substrate 100.

(f) Further, as a result of intensive studies, it has been found that a property of a thin film to be formed can be changed by performing the processing by changing a ratio of the nitrogen gas to the hydrogen gas in the processing gas. Hereinbelow, a modification of the sheet resistance ratio in the case of changing the ratio of the nitrogen gas in the processing gas will be described.

FIG. 7 shows a graph comparing the sheet resistance ratio of the thin film processed by changing the ratio between the nitrogen gas (N₂) and the hydrogen gas (H₂), the sheet resistance ratio of the processed thin film after being exposed to the oxygen atmosphere, and the sheet resistance ratio of the thin film that has been exposed to the oxygen atmosphere without being subjected to the aforementioned nitriding. Note that the exposure to the oxygen (O₂) atmosphere was performed for 120 seconds with the O₂ gas atmosphere, the gas pressure of 200 Pa, and the wafer temperature of 450° C. In any case, the value of the sheet resistance of the titanium nitride film to which the aforementioned substrate processing step has not been performed and that is before being exposed to the oxygen atmosphere is set as 1 (reference).

As shown in FIG. 7, it can be understood that the sheet resistance of the titanium nitride film can be reduced by performing the aforementioned substrate processing step. Further, the sheet resistance ratio becomes 0.89 or less in a range where the ratio of nitrogen gas to hydrogen in the processing gas is 0 or more and 0.75 or less, and the sheet resistance ratio can more effectively be reduced, whereby a refinement of integrated circuits and a property required in a semiconductor device in recent years can be realized. Further, even with the thin film that has been exposed to the oxygen atmosphere after the nitriding, the sheet resistance ratio becomes about 0.92 or less when the ratio of nitrogen gas to hydrogen in the processing gas in performing the nitriding is in a range of larger than 0 and 0.75 or less, and the property can be maintained even if an oxide film is formed on the titanium nitride film. Accordingly, it can be understood that, by performing the aforementioned substrate processing step, not only the reduction in the electric resistance of the titanium nitride film but also the oxidation resistance can be improved. Further, as seen from FIG. 7, in a process in which the ratio of the nitrogen gas to the hydrogen in the processing gas is 0, that is, in a process performed with the ratio of the hydrogen gas as 1.0, the sheet resistance after the process is reduced, but an increase rate of the sheet resistance after the oxygen atmosphere exposure is made larger. It is therefore expected that although the chlorines and oxygen contained in the titanium nitride can be reduced by the processing using only the hydrogen, dangling bonds remain, which brings a state of easily being oxidized. Contrary to this, in a case of processing with the ratio of the nitrogen gas to the hydrogen within the processing gas as 1.0, no significant change can be seen in the sheet resistance after the processing, and the change in the resistance after the oxygen atmosphere exposure is smaller. From this result, it is considered that the oxidation resistance is improved by supplying the nitrogen to the surface of the titanium nitride film. According to the above results, it can be understood that both advantages of reduction of the sheet resistance and the improvement in the oxidation resistance can be achieved by mixing the gas containing the hydrogen atoms and the nitrogen atom-containing gas and performing the plasma processing thereby. Further, it can be understood that the processing should be performed only with hydrogen in a case of simply improving the sheet resistance, and should be performed only with nitrogen in a case of simply improving the oxidation resistance.

(g) Further, it has been found that, similarly by using the nitrogen gas (N₂) and the ammonia gas (NH₃) as the processing gas, the residual amount of the chlorine atoms and the residual amount of the oxygen atoms in the titanium nitride film can be reduced, the electric resistance of the titanium nitride film can be reduced, and the oxidation resistance can be improved.

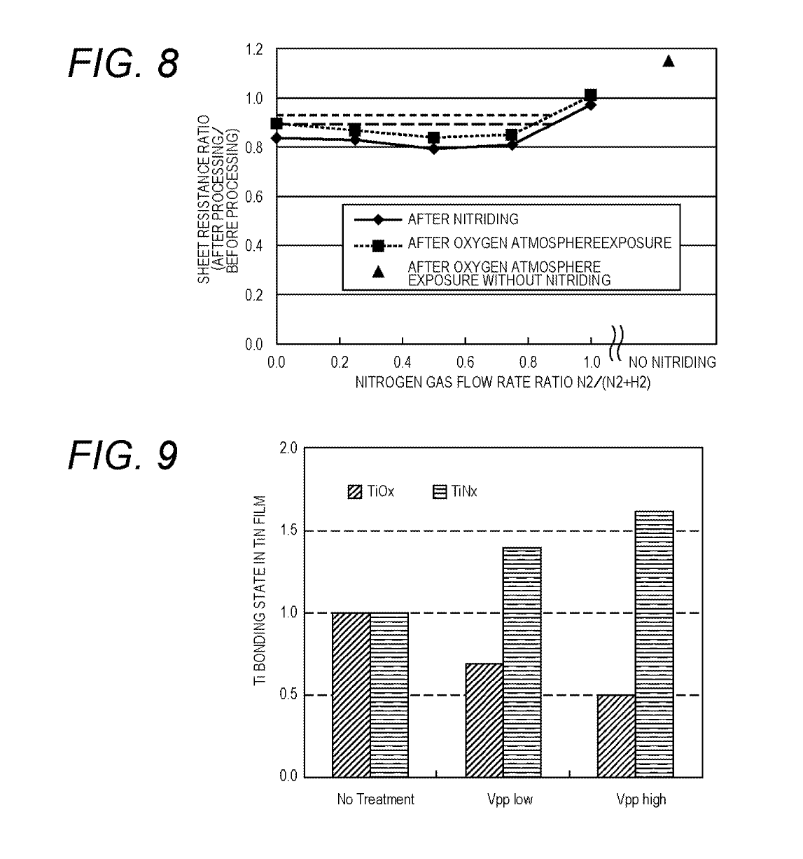

FIG. 8 is a graph comparing the sheet resistance ratio of the thin film processed by changing the flow rates of the nitrogen (N₂) and the ammonia gas (NH₃), the sheet resistance ratio of the processed thin film after being exposed to the oxygen atmosphere, and the sheet resistance ratio of the thin film that has been exposed to the oxygen atmosphere without being subjected to the aforementioned processing. Note that the exposure to the oxygen (O₂) atmosphere was performed for 120 seconds with the O₂ gas atmosphere, the gas pressure of 200 Pa, and the wafer temperature of 450° C. In any case, the value of the sheet resistance of the titanium nitride film to which the aforementioned substrate processing step has not been performed and that is before being exposed to the oxygen atmosphere is set as 1 (reference).

As shown in FIG. 8, it can be understood that the sheet resistance of the titanium nitride film can be reduced by performing the aforementioned substrate processing step. Further, it can be understood that the sheet resistance ratio becomes 0.89 or less in a range where the ratio of nitrogen gas to ammonia gas in the processing gas is 0 or more and 0.87 or less, and the sheet resistance ratio can more effectively be reduced, whereby the refinement of integrated circuits and the property required in the semiconductor device in recent years can be realized. Further, even with the thin film that has been exposed to the oxygen atmosphere after the nitriding, the sheet resistance ratio becomes about 0.92 or less when the ratio of nitrogen gas to ammonia gas in the processing gas in performing the nitriding is in a range of 0 or more and 0.87 or less, and the property can be maintained even if an oxide film is formed on the titanium nitride film. Accordingly, by performing the aforementioned substrate processing step, the electric resistance of the titanium nitride film can be reduced. Further, it can be understood that the oxidation resistance to active oxygen species such as ozone (O₃) or O₂ plasma used in forming a high-k film formed on the titanium nitride film can be improved.

(h) Further, as a result of intensive studies, it has been found that a property of the film formed on the silicon substrate 100 can be improved by changing the voltage Vpp to be applied to the second electrode 217c. Hereinbelow, a modification of TiOₓ and TiNₓ concentrations in the TiN film in a case with the voltage Vpp of 50 V to 300 V, for example, when the change is caused to take place with the voltage Vpplow (50 V) and the voltage Vpphigh (300 V).

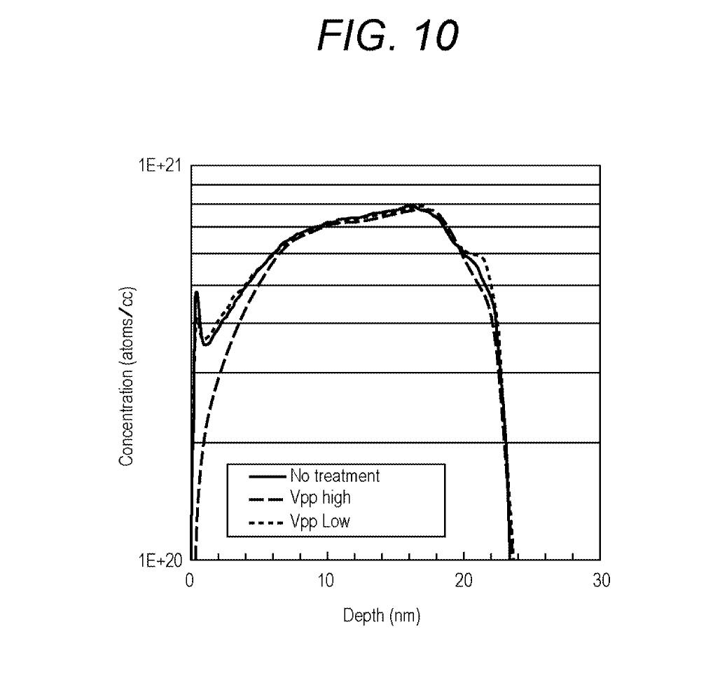

FIG. 9 is a graph comparing change rates of the TiOₓ and TiNₓ concentrations in the film processed by changing the voltage Vpp for the silicon substrate 100, and the TiOₓ and TiNₓ concentrations in the film before the processing. The TiOₓ and TiNₓ concentrations before the processing are set as 1 (reference).

As shown in FIG. 9, it can be understood that, by applying the aforementioned voltage Vpp, the TiOₓ concentration in the titanium nitride film is reduced, and the TiNₓ concentration is increased. Further, it can be understood that the increasing amount of TiNₓ is larger than the reduction rate of TiOₓ. Especially, it can be understood that TiOₓ is reduced and TiNₓ is formed at a larger degree in the case of Vpphigh. By applying the voltage Vpp in this manner, it becomes possible to take in a large amount of N into the film while reducing O in the film. With the large amount of N being taken in, the improvement in the oxidation resistance of the film can be expected.

FIG. 10 is a graph showing a chlorine concentration in the titanium nitride film upon performing the processing under the same condition.

As shown in FIG. 10, it can be understood that the chlorine concentration in the film is decreased by increasing the voltage Vpp to be applied to the second electrode 217c. Thus, it is considered that impurities in the film can be removed by applying the voltage Vpp, and the electric property can be improved similarly to the other examples as aforementioned.

From FIGS. 9 and 10, it is considered that hydrogen and nitrogen are more likely to be drawn into the silicon substrate 100 by increasing the voltage Vpp to be applied to the second electrode 217c, whereby the oxygen and chlorine in the film are removed, and the electric property can be improved while the oxidation resistance of the titanium nitride film is improved by the nitrogen being taken into the generated vacancies. Thus, even in a case of forming a capacitor layer on the titanium nitride film by using ozone (O₃) and oxygen (O₂) plasma, it is considered that the titanium nitride film is prevented from being oxidized.

The aforementioned capacitor layer is a high-k film, and is for example ZrO. Such a ZrO film is formed by using tetrakis ethylmethylamino zirconium (TEMAZ) and ozone (O₃) gas, in an atmosphere of about 250° C.

### Other Embodiments of Invention

The embodiments have been described above specifically, but the present invention is not limited to the aforementioned embodiments and can be modified in various manners without departing from the spirit of the present invention.

For example, in the aforementioned embodiments, the case of processing the silicon substrate 100 on the surface of which the titanium nitride film is formed has been described. However, the invention is not limited to such a configuration, and may similarly process other substrates containing chlorine atoms and metallic atoms, such as a glass substrate on the surface of which the titanium nitride film is formed.

Further, for example, in the aforementioned embodiments, the case of using the mixed gas of the H₂ gas and the N₂ gas and the case of using the mixed gas of the NH₃ gas and the N₂ gas as the reactant gas have been described. However, the invention is not limited to such configurations. Depending on various conditions such as an amount of remaining chlorine in the titanium nitride film, processing temperature, processing pressure, and supply flow rate, the NH₃ gas alone, the mixed gas of NH₃ gas and the H₂ gas, the mixed gas of NH₃ gas and the N₂ gas, the N₂ gas alone, a monomethylhydrazine (CH₆N₂) gas, or a gas obtained by mixing these gases at arbitrary rates can be used as the reactant gas, for example. Further, the gas containing nitrogen and the gas containing hydrogen as aforementioned may alternately be supplied.

Further, in the aforementioned embodiments, although the natural oxide film has been described as an example of the oxide film formed on the substrate, the invention is not limited to this example. For example, the natural oxide film may be removed before moving the substrate into the present apparatus. In this case, since the natural oxide film is absent from the substrate surface, it becomes possible to surely remove the oxygen atoms mixed into the substrate.

### Preferred Embodiments

Hereinbelow, the preferred embodiments will supplementarily be described.

### Supplementary Note 1

According to one embodiment, there is provided a substrate processing apparatus including:

a process chamber into which a substrate is carried, wherein a chlorine atom-containing metal nitride film, in which a natural oxide film is formed on a top side thereof, is formed on the substrate;

a substrate support unit configured to support and heat the substrate within the process chamber;

a gas supply unit configured to supply either or both of nitrogen atom-containing gas and hydrogen atom-containing gas to an inside of the process chamber;

a gas exhaust unit configured to exhaust the gas from the inside of the process chamber;

a plasma generation unit configured to excite the nitrogen atom-containing gas and the hydrogen atom-containing gas supplied to the inside of the process chamber; and

a control unit configured to control the substrate support unit, the gas supply unit, and the plasma generation unit.

### Supplementary Note 2

Preferably, the metal nitride film described in the Supplementary Note 1 is a titanium nitride film.

### Supplementary Note 3

Preferably, the metal nitride film described in the Supplementary Note 1 is a lower electrode of a capacitor.

### Supplementary Note 4

Preferably, the capacitor described in the Supplementary Note 3 is a high-k film.

### Supplementary Note 5

Preferably, the plasma generation unit described in the Supplementary Note 1 is provided to generate plasma within the process chamber.

### Supplementary Note 6

Preferably, the nitrogen atom-containing gas described in the Supplementary Note 1 is any of a nitrogen gas, an ammonia gas, and a monomethylhydrazine gas, and the hydrogen atom-containing gas is any of a hydrogen gas, an ammonia gas, and a monomethylhydrazine gas.

### Supplementary Note 7

Preferably, a ratio of a nitrogen gas to a hydrogen gas supplied into the process chamber described in the Supplementary Note 1 is in a range of 0 or more and 0.75 or less.

### Supplementary Note 8

More preferably, the ratio of the nitrogen gas to the hydrogen gas supplied into the process chamber described in the Supplementary Note 1 is in a range of larger than 0 and 0.75 or less.

### Supplementary Note 9

Preferably, a ratio of the nitrogen gas to a gas containing nitrogen and hydrogen supplied into the process chamber described in the Supplementary Note 1 is in a range of 0 or more and 0.87 or less.

### Supplementary Note 10

According to another embodiment, there is provided a method of manufacturing a semiconductor device, the method including:

carrying a substrate into a process chamber and supporting the substrate by a substrate support unit, wherein a chlorine atom-containing metal nitride film, in which a natural oxide film is formed on a top side thereof, is formed on the substrate;

heating the substrate by the substrate support unit;

supplying nitrogen atom-containing gas and hydrogen atom-containing gas by a gas supply unit to an inside of the process chamber and exhausting the process chamber by a gas exhaust unit; and

exciting the nitrogen atom-containing gas and the hydrogen atom-containing gas supplied into the process chamber by a plasma generation unit.

### Supplementary Note 11

According to yet another embodiment, there is provided a method of manufacturing a semiconductor device, the method including:

carrying a substrate into a process chamber, wherein a chlorine atom-containing metal nitride film, in which a natural oxide film is formed on a top side thereof, is formed on the substrate;

processing the substrate within the process chamber with a reactant gas containing excited nitrogen atoms; and

taking out the substrate from the process chamber.

### Supplementary Note 12

Preferably, the reactant gas described in the Supplementary Note 11 further contains hydrogen atoms.

### Supplementary Note 13

Preferably, the metal nitride film described in the Supplementary Note 11 is a titanium-containing film.

### Supplementary Note 14

Preferably, the reactant gas described in the Supplementary Note 11 is an ammonia gas, or a mixed gas of nitrogen components and ammonia components.

### Supplementary Note 15

According to yet another embodiment, the reactant gas described in the Supplementary Notes 1 to 14 is diluted with a noble gas.

### Supplementary Note 16

According to yet another embodiment, there is provided a substrate processing apparatus including:

a process chamber into which a substrate is carried, wherein a chlorine atom-containing metal nitride film, in which a natural oxide film is formed on a top side thereof, is formed on the substrate;

a gas supply unit configured to supply a reactant gas to an inside of the process chamber;

a plasma generation unit configured to excite the reactant gas within the process chamber; and

a control unit configured to control the gas supply unit and the plasma generation unit so that the substrate is processed within the process chamber with the reactant gas containing excited nitrogen atoms.

### Supplementary Note 17

According to yet another embodiment, there is provided a substrate processing apparatus including:

a process chamber into which a substrate is carried, wherein a chlorine atom-containing metal nitride film, in which a natural oxide film is formed on a top side thereof, is formed on the substrate;

a substrate support unit configured to support and heat the substrate within the process chamber;

a gas supply unit configured to supply a nitrogen atom-containing first processing gas and a hydrogen atom-containing second processing gas alternately to an inside of the process chamber;

a gas exhaust unit configured to exhaust the process chamber;

a plasma generation unit configured to excite the first processing gas and the second processing gas supplied into the process chamber; and

a control unit configured to control the substrate support unit, the gas supply unit, the gas exhaust unit, and the plasma generation unit.

### Supplementary Note 18

According to yet another embodiment, the substrate support unit described in the Supplementary Notes 1 to 17 has a second electrode provided thereon, and a voltage Vpp is applied to the substrate.

### INDUSTRIAL APPLICABILITY

According to the substrate processing apparatus and the method of manufacturing a semiconductor device of the embodiment, the residual amounts of the chlorine atoms and the oxygen atoms in the metal nitride film can be reduced in the temperature range that does not deteriorate the property of other films adjacent to the metal nitride film, and the oxidation resistance can be improved while the property of the metal nitride film is improved.

### REFERENCE SIGNS LIST

100 Silicon substrate (substrate)
201 Process chamber
121 Controller (control unit)

1. A substrate processing apparatus comprising:
a process chamber into which a substrate is carried, wherein a chlorine atom-containing metal nitride film, in which a natural oxide film is formed on a top side thereof, is formed on the substrate;
a substrate support unit configured to support and heat the substrate within the process chamber;
a gas supply unit configured to supply either or both of nitrogen atom-containing gas and hydrogen atom-containing gas to an inside of the process chamber;
a gas exhaust unit configured to exhaust the gas from the inside of the process chamber;
a plasma generation unit configured to excite the gas supplied to the inside of the process chamber; and
a control unit configured to control the substrate support unit, the gas supply unit, and the plasma generation unit.

2. The substrate processing apparatus according to claim 1, wherein
the metal nitride film is a titanium nitride film.

3. The substrate processing apparatus according to claim 1, wherein
the nitrogen atom-containing gas is any of a nitrogen gas, an ammonia gas, and a monomethylhydrazine gas, and
the hydrogen atom-containing gas is any of a hydrogen gas, an ammonia gas, and a monomethylhydrazine gas.

4. The substrate processing apparatus according to claim 1, wherein
a second electrode is provided on the substrate support unit, and an impedance changing mechanism is connected to the substrate support unit, and
the control unit controls the impedance changing mechanism so as to apply a voltage Vpp to the substrate.

5. A method of manufacturing a semiconductor device, the method comprising:
carrying a substrate into a process chamber and supporting the substrate by a substrate support unit, wherein a chlorine atom-containing metal nitride film, in which a natural oxide film is formed on a top side thereof, is formed on the substrate;
heating the substrate by the substrate support unit;
supplying, by a gas supply unit, either or both of nitrogen atom-containing gas and hydrogen atom-containing gas to an inside of the process chamber; and
exciting, by a plasma generation unit, the gas supplied to the inside of the process chamber.
